(19) United States
(12) Patent Application Publication
(10) Pub. No.: US 2007/0095381 A1
(43) Pub. Date: May 3, 2007

(54) Stacked thermoelectric device for power generation

(75) Inventor: Te-Hsi Lee, Taipei (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD.

(21) Appl. No.: 11/260,108

(22) Filed: Oct. 28, 2005

(51) Int. Cl. H01L 35/02

(52) U.S. Cl. 136/230

(57) ABSTRACT

A thermoelectric device comprises a substrate comprising a thermal insulating region and a thermal conductive region, in which a dielectric layer is formed on the substrate of the thermal insulating region and a thermal insulating cavity formed between the substrate and the overlying-dielectric layer. A stack structure overlies the substrate of the thermal insulating and conductive regions comprising a plurality of thermoelectric material layers insulated from each other. First and second interconnect structures overlie the substrate of the thermal insulating and conductive regions, respectively, electrically connecting the stack structure. A method for fabricating the same is also disclosed.

### BACKGROUND

The present invention relates to a microfabricated thermoelectric device, and particularly to a stacked thermoelectric device for powering an electronic component and method for fabricating the same.

Thermoelectric effects, such as the Seebeck effect, are well known. Two different metals are connected at one end, to form a thermocouple. When a temperature gradient is provided between the connected end (normally the hot end) and the other end (normally the cold end), a voltage can be measured therebetween. To obtain the most effective conversion of the temperature gradient into voltage, a large number of thermoelectric couples are connected in series to form a thermoelectric module. By heating the hot junctions and/or cooling the cold junctions, an electromotive force is generated at the terminals of the set of thermoelectric couples. That is, the electrical power can be produced by this generator for supplying a load.

It has been proposed to replace metals with differently (n- and p-) doped semiconductors to form such a set of series-connected thermoelectric couples. These semiconductor thermoelectric couples have a thermoelectric power markedly higher than that of the metal thermoelectric couples. However, the known semiconductor generators have not hitherto been able to be fabricated reliably and economically.

Thus, a need exists in the microfabricating art to develop an improved thermoelectric device, thereby improving thermal converting performance and device reliability.

### SUMMARY

A thermoelectric device and a method for fabricating the same are provided. An embodiment of a thermoelectric device comprises a substrate comprising a thermal insulating region and a thermal conductive region, in which a dielectric layer is formed on the substrate of the thermal insulating region and a thermal insulating cavity is formed between the substrate and the overlying dielectric layer. A stack structure overlies the substrate of the thermal insulating and conductive regions, comprising a plurality of thermoelectric material layers insulated from each other. First and second interconnect structures overlie the substrate of the thermal insulating and conductive regions, respectively, electrically connecting the stack structure.

An embodiment of a method for fabricating a thermoelectric device comprises providing a substrate comprising a first region and a second region. First and second dielectric layers are formed overlying the substrate of the first and second regions, respectively, in which the first dielectric layer is thicker than the second dielectric layer. A stack structure is formed overlying first and second dielectric layers, comprising a plurality of thermoelectric material layers insulated from each other. First and second interconnect structures are formed overlying the substrate of the first and second regions, respectively, electrically connecting to the stack structure.

### DESCRIPTION OF THE DRAWINGS

The invention will become more fully understood from the detailed description given hereinbelow and the accompanying drawings, given by way of illustration only and thus not intended to be limitative of the invention.

FIGS. 1A to 1J are perspective views of an embodiment of a method for fabricating a thermoelectric device.

FIG. 2 is a perspective view of an embodiment of an electronic device comprising thermoelectric devices.

### DESCRIPTION

The invention is directed to a stacked thermoelectric device, such as a thermoelectric generator (TEG), and method of fabricating the same.

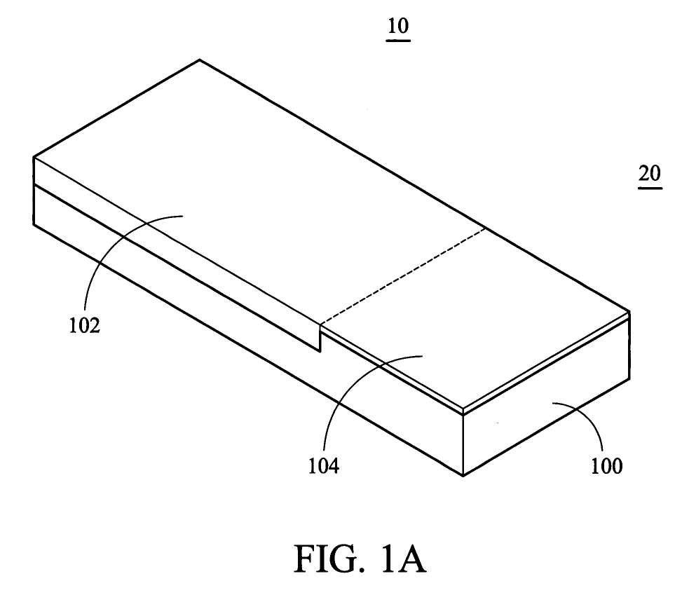

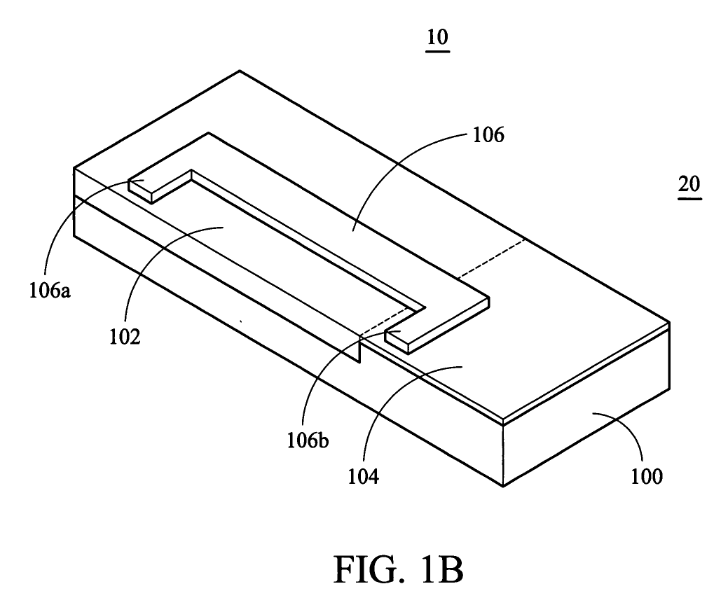

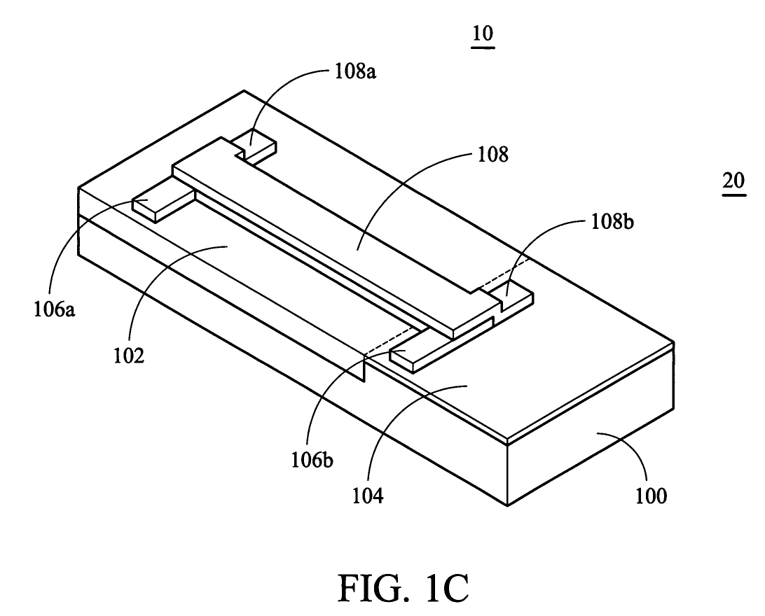

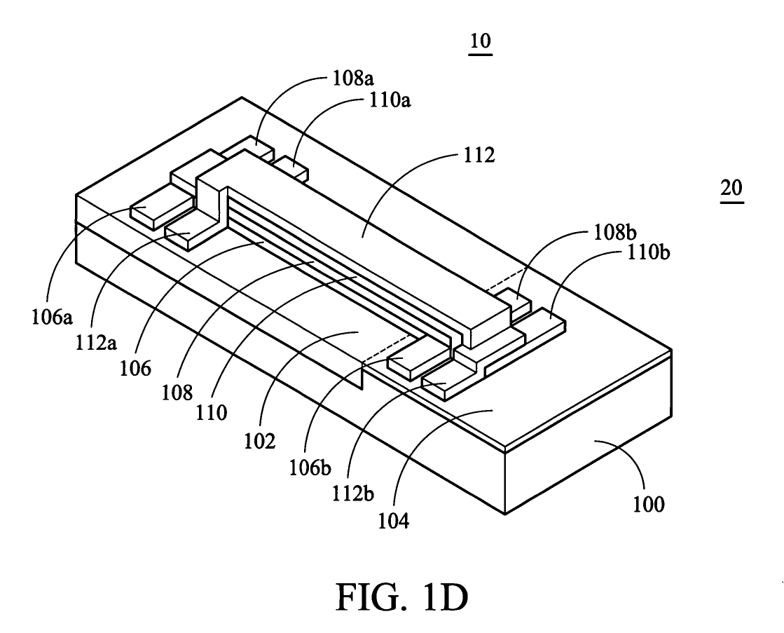

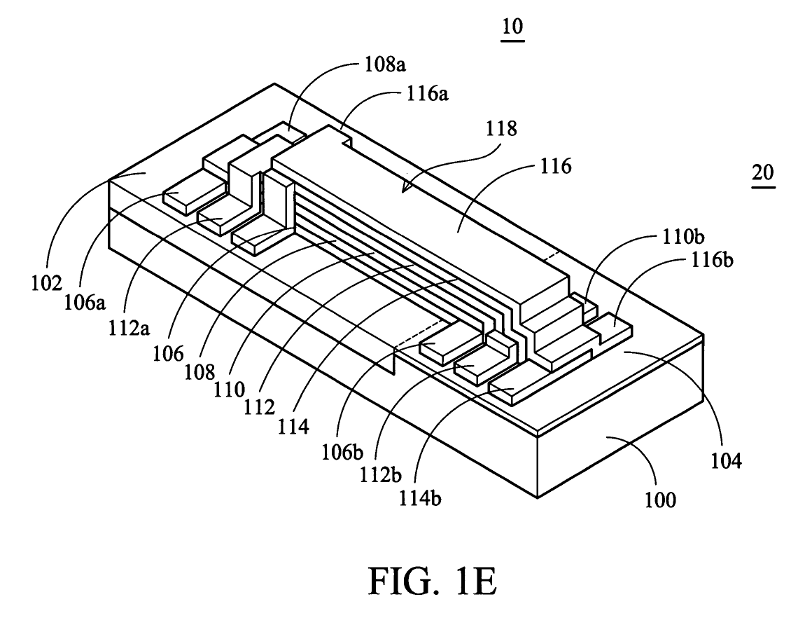

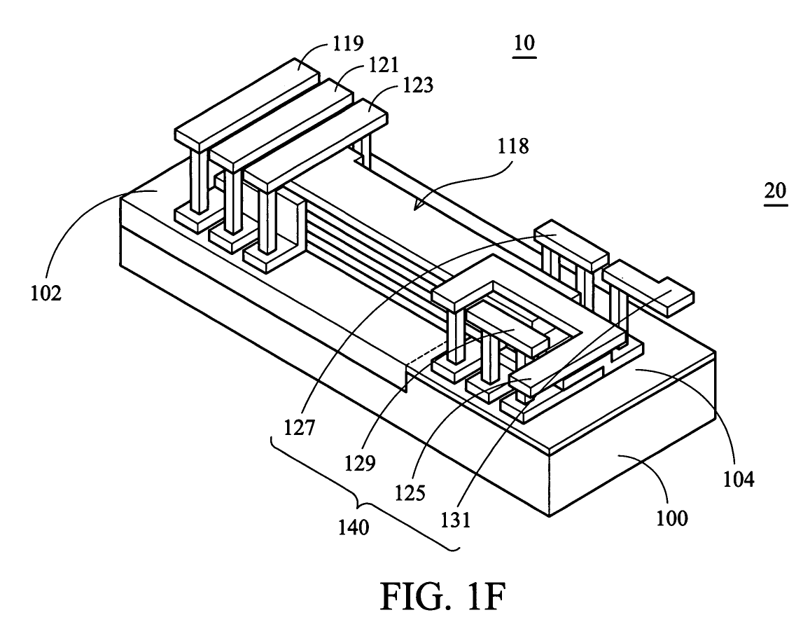

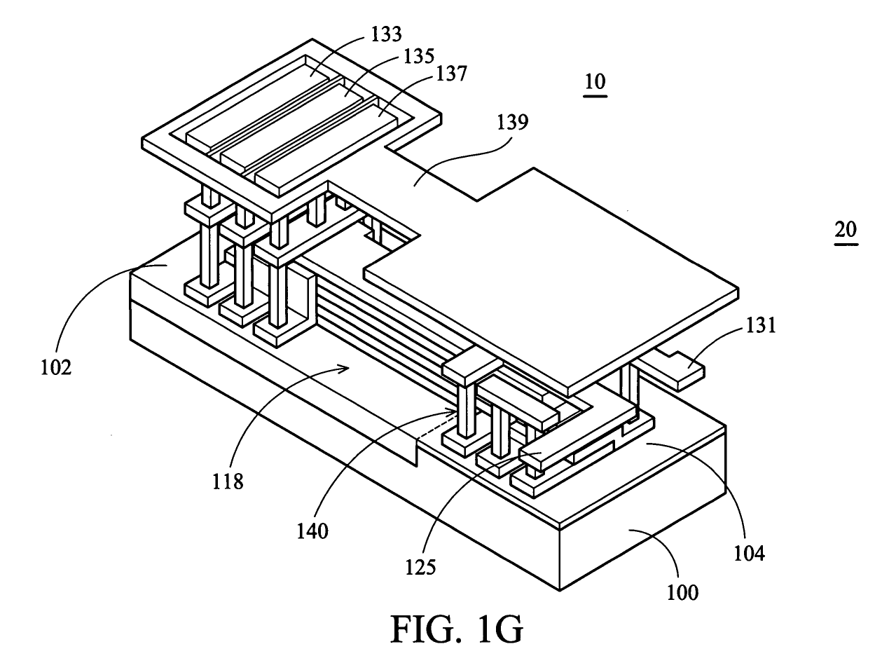

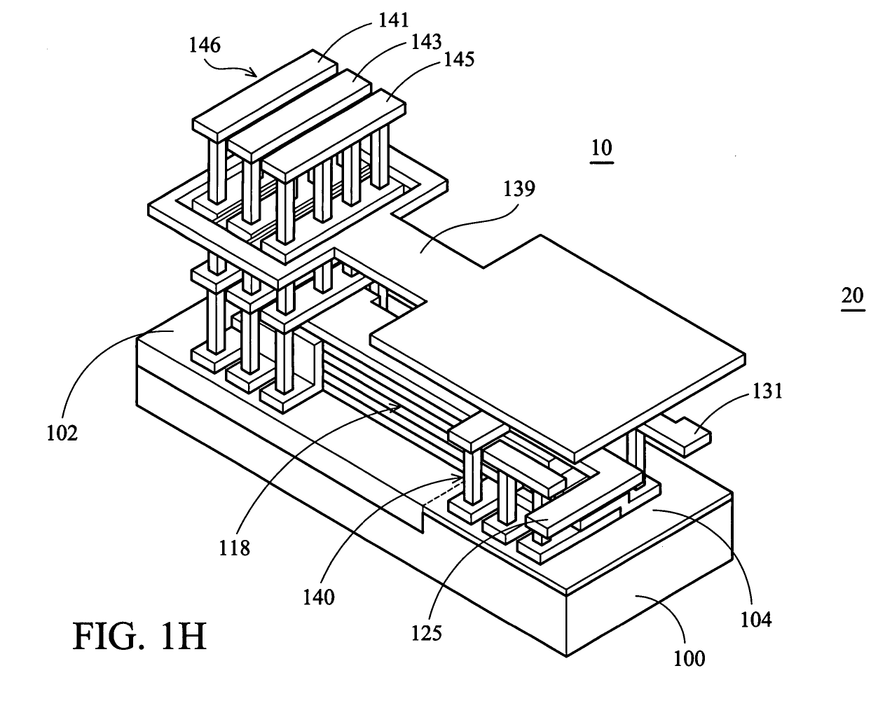

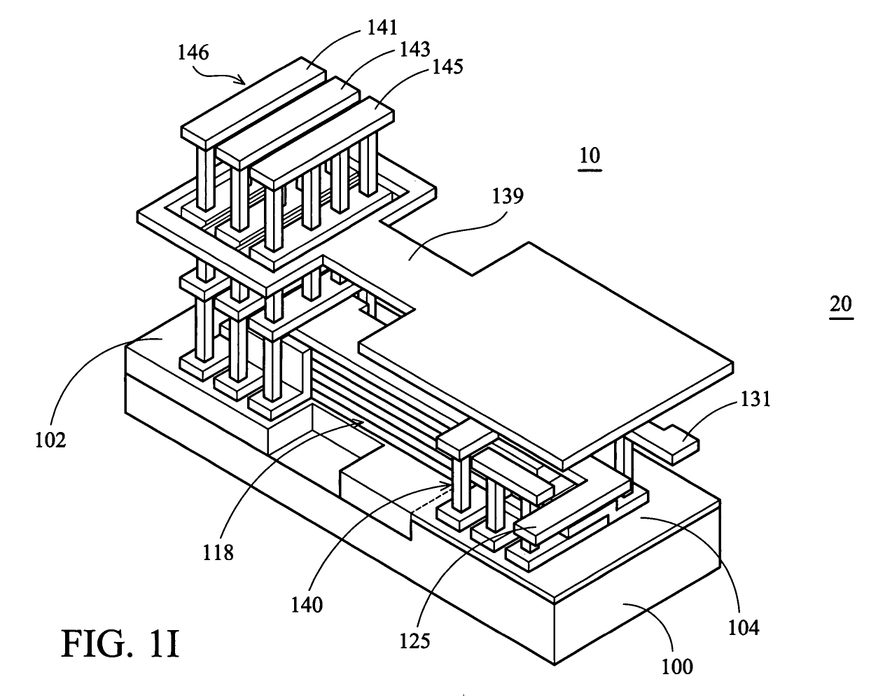

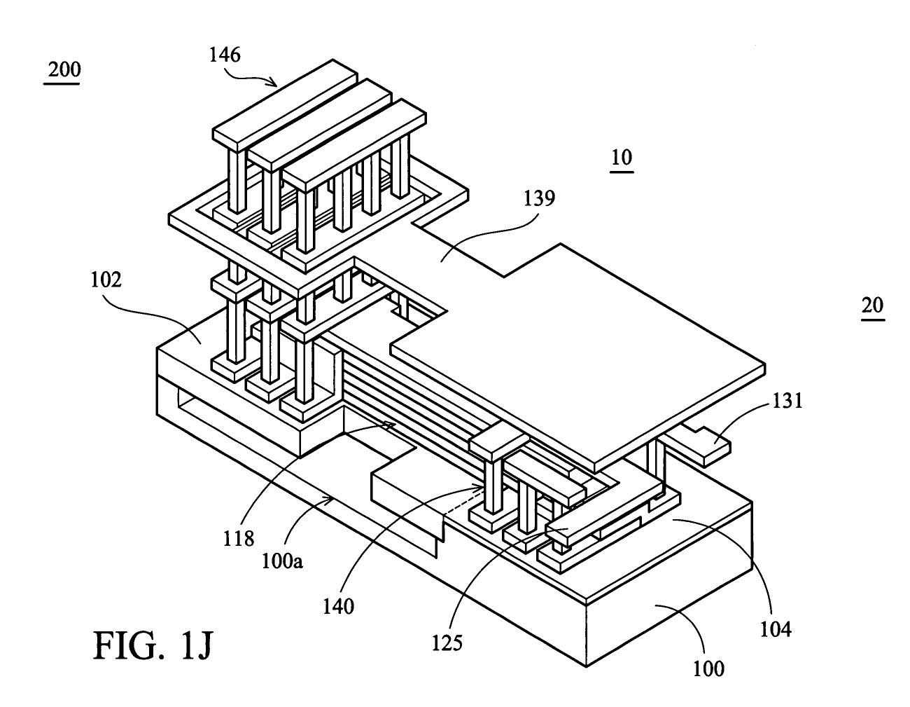

FIG. 1J illustrates a perspective diagram of an embodiment of a stacked thermoelectric device 200. The device 200 comprises a substrate 100 comprising a thermal insulating region 10 and a thermal conductive region 20. A first dielectric layer 102, such as a field oxide formed by the LOCOS or STI, is formed on the substrate 100 of the thermal insulating region 10. A second dielectric layer 104, such as a thin oxide layer, may be formed on the substrate 100 of the thermal conductive region 20 by thermal oxidation. The first dielectric layer 102 in the thermal insulating region 10 is thicker than the second dielectric layer 104 in the thermal conductive region 20, thereby providing good thermal insulation. A thermal insulating cavity 100a is formed between the substrate 100 and the overlying first dielectric layer 102, thereby further enhancing the thermal insulation in the thermal insulating region 10.

A plurality of thermoelectric material layers overlies the substrate 100 of the thermal insulating and conductive regions 102 and 104 to form a stack structure 118. In this embodiment, the thermoelectric material layers may comprise silicon, such as doped polysilicon, doped amorphous silicon or SiGe, or other semiconductor materials,. such as BiTe. For example, the thermoelectric material layers may comprise a plurality of first semiconductor layers with a first type conductivity. (for example, n-type polysilicon layers) and a plurality of second semiconductor layers with a second type conductivity opposite to the first type conductivity (for example, p-type polysilicon layers), in which the first and second semiconductor layers are alternately arranged. Insulating layers (not shown), such as oxide layers, are successively sandwiched between each of the first and second semiconductor layers, such that the first and second semiconductor layers are insulated from each other.

A first interconnect structure 146 overlies the substrate 100 of the thermal insulating region 10, and a second interconnect structure 140 overlies the substrate 100 of the thermal conductive region 20. Moreover, the first and second interconnect structures 146 and 140 are electrically connected to the stack structure 118. In this embodiment, the first and second interconnect structures 146 and 140 may comprise multi-level metals and plugs formed in interlayer dielectric (ILD) and/or intermetal dielectric (IMD) layers (not shown) on the substrate 100. The substrate 100 of the thermal conductive region 20, the stack structure 118 and the first interconnect structure 146 create a heat flux path, such that voltage (power) is output from the second interconnect structure 140 when heat passes through the heat flux path from the bottom surface of the substrate 100. That is, the top surface of the first interconnect structure 146 serves a cold junction of the. thermoelectric device 200 and the bottom surface of the substrate 100 as a hot junction. When heat passes through the heat flux path from the hot junction, temperature difference or gradient is produced between the cold and hot junctions, thus a voltage can be generated from the thermoelectric device 200 for powering a load, such as an electronic circuit or component or an external electronic device.

FIGS. 1A to 1J illustrate perspective diagrams of an embodiment of a method for fabricating a thermoelectric device. In FIG. 1A, a substrate 100, such as a silicon substrate or other semiconductor substrate, comprising a first region 10 and a second region 20 adjacent thereto is provided. Here, the first region 10 serves as a thermal insulating region and the second region 20 as a thermal conductive region. First and second dielectric layers 102 and 104 are formed overlying the substrate 100 of the first and second regions 10 and 20; respectively. In this embodiment, the first dielectric layer 102 is thicker than the second dielectric layer 104. For example, the first dielectric layer 102 can be a field oxide formed by conventional isolation technologies such as local oxidation of silicon (LOCOS) or shallow trench isolation. Moreover, the second dielectric layer 104 can be a growth oxide formed by thermal oxidation. The first dielectric layer 102 provides an etch protection in subsequent processes and the second dielectric layer 104 serves as a thermal contact for the substrate 100 in the second region 20.

Next, in FIG. 1B, a first thermoelectric material layer 106 is formed on the first and second dielectric layers 102 and 104. In this embodiment, the first thermoelectric material layer 106 comprises a line portion and two protruding portions 106a and 106b. The protruding portions 106a and 106b are in the first and second regions 10 and 20, respectively. For example, the protruding portions 106a and 106b can be at both ends of the line portion, respectively, extending along a direction substantially perpendicular to the line portion, such that the first thermoelectric material layer 106 has a U-shaped profile.

Next, in FIG. 1C, a U-shaped second thermoelectric material layer 108 comprising a line portion and two protruding portions 108a and 108b is formed overlying the first thermoelectric material layer 106 and insulated therefrom by a dielectric layer (not shown), in which the line portion overlaps that of the first thermoelectric material layer 106 and the protruding portions 108a and 108b on the first and second dielectric layers 102 and 104, respectively, extend along a direction opposite to that of the protruding portions 106a and 106b and substantially aligned therewith. In this embodiment, the first thermoelectric material layer 106 may be a semiconductor layer comprising silicon with a first type conductivity, and the second thermoelectric material layer 108 may be a semiconductor layer comprising silicon with a second type conductivity opposite to the first type conductivity, thereby forming a first thermoelectric couple. For example, the first and second thermoelectric material layers 106 and 108 can be n-type and p-type polysilicon, respectively. Additionally, the first and second thermoelectric material layers 106 and 108 may comprise amorphous silicon, SiGe or BiTe.

Next, in FIG. 1D, third and fourth thermoelectric material layers 110 and 112 having U-shaped profiles are successively formed overlying the second thermoelectric material layer 108 to form a second thermoelectric couple similar to the first thermoelectric couple. The third thermoelectric material layer 110 is insulated from the underlying second thermoelectric material layer 108 and the overlying fourth thermoelectric material layer 112 by dielectric layers (not shown). Moreover, the protruding portions 110a and 110b extend along the same direction as the protruding portions 108a and 108b, and the protruding portions 112a and 112b extend along the same direction as the protruding portions 106a and 106b. The protruding portions 112a and 112b are substantially aligned to the protruding portions 110a and 110b, respectively. Also, the third thermoelectric material layer 110 may be a semiconductor layer comprising silicon with the first type conductivity, and the fourth thermoelectric material layer 112 may be a semiconductor layer comprising silicon with the second type conductivity. For example, the third and fourth thermoelectric material layers 110 and 112 can be n-type and p-type polysilicon layer, respectively.

Next, in FIG. 1E, a similar third thermoelectric couple is formed overlying the second thermoelectric couple and insulated therefrom, comprising fifth and sixth thermoelectric material layers 114 and 116 having U-shaped profiles and insulated from each other. The protruding portions 114a and 114b extend along the same direction as the protruding portions 106a and 106b, and the protruding portions 116a and 116b extend along the same direction as the protruding portions 108a and 108b. The protruding portions 116a and 116b are substantially aligned to the protruding portions 114a and 114b, respectively. Also, the fifth thermoelectric material layer 114 may be a semiconductor layer comprising silicon with the first type conductivity, and the sixth thermoelectric material layer 116 may be a semiconductor layer comprising silicon with the second type conductivity. For example, the fifth and sixth thermoelectric material layers 114 and 116 can be n-type and p-type polysilicon, respectively.

The thermoelectric material layers 106, 108, 110, 112, 114 and 116 form a thermoelectric stack structure 118, in which the thermoelectric material layers 106, 110 and 114 with the first type conductivity and the thermoelectric material layers 108, 112 and 116 with the second type conductivity are alternately arranged. Moreover, all the protruding portions 106a, 108a, 110a, 112a, 114a and 116a are arranged in the first region 10 and all the protruding portions 106b, 108b, 110b, 112b, 114b and 116b are arranged in the second region 20 without overlapping.

FIGS. 1F to 1H illustrate the steps of forming first and second interconnect structures 146 and 140 overlying the substrate 100 of the first and second regions 10 and 20, respectively, to electrically connect the stack structure 118. In FIG. 1F, metal layers 119, 121 and 123 are formed in the first region 10 by, for example, a damascene process, to electrically connect the protruding portions 106a and 108a, the protruding portions 110a and 112a and the protruding portions 114a and 116a, respectively, through the underlying conductive plugs. Thus a portion of the first interconnect structure 146 is formed. Metal layers 127 and 129 are formed in the second region 20 to electrically connect the protruding portions 108b and 110b and the protruding portions 112b and 114b, respectively, through the underlying conductive plugs. Moreover, the metal layers 125 and 131 are also formed in the second region 20 to electrically connect the protruding portions 106b and 116b, respectively, through the underlying conductive plugs, serving as input/output terminals. The metal layers 125, 127, 129 and 131 and the plugs thereunder form the second interconnect structure 140. The metal layers 119, 121, 123, 125, 127, 129 and 131 and the plugs thereunder are formed in a first IMD layer (not shown), which connect the first, second and third thermoelectric couples in series.

Next, in FIG. 1G, metal layers 133, 135 and 137 are formed in the first region 10 by, for example, a damascene process, to electrically and thermally connect the metal layers 119, 121 and 123, respectively, through the underlying conductive plugs to form another portion of the first interconnect structure 146. Moreover, a metal layer 139 is formed in the first and second regions 10 and 20 to cover the stack structure 118 and the second interconnect structure 140 and surround the metal layers 133, 135 and 137. Typically, the metal layers 133, 135, 137 and 139 is and the plugs thereunder are formed in a second IMD layer (not shown) formed on the first IMD layer. In this embodiment, a portion of the first dielectric layer 102 on both sides of the line portion of the first thermoelectric material layer 106 is uncovered by the metal layer 139.

Next, in FIG. 1H, metal layers 141, 143 and 145 are formed in the first region 10 by, for example, a damascene process, to electrically and thermally connect the metal layers 133, 135 and 137, respectively, through the underlying conductive plugs to complete the first interconnect structure 146. Typically, the metal layers 141, 143 and 145 and the plugs therebeneath are formed in a third IMD layer (not shown) formed on the second IMD layer. Next, the third IMD layer is etched using the metal layer 139 as a stop layer.

Next, in FIG. 1I, the second and first TMD layers and the underlying first dielectric layer 102 are successively etched using the metal layer 139 as an etch mask, to expose a portion of the underlying substrate 100 of the first region 10. In this embodiment, the second and first IMD layers and the underlying first dielectric layer 102 can be etched by, for example, reactive ion etching (RIE) using C₄F₈ as an etchant.

Finally, in FIG. 1J, the exposed substrate 100 is isotropically etched to form a cavity 110a therein and underlying the first dielectric layer 102, completing the fabrication of the stacked thermoelectric device 200. The cavity 110a in the first region 10 provides a good thermal insulation. In this embodiment, the isotropic etching can be performed using SF₆ as an etchant. Here, the substrate 100 in the second region 20, the second dielectric layer 104, the stack structure 118 and the first interconnect structure 146 create a heat flux path using the top surfaces of the metal layers 141, 143 and 145 as cold side contacts and the bottom surface of the substrate 100 as a hot side contact, providing voltage (power) between the input/output terminals 125 and 131 of the second interconnect structure 140 when heat passes through the heat flux path from the bottom surface of the substrate-100.

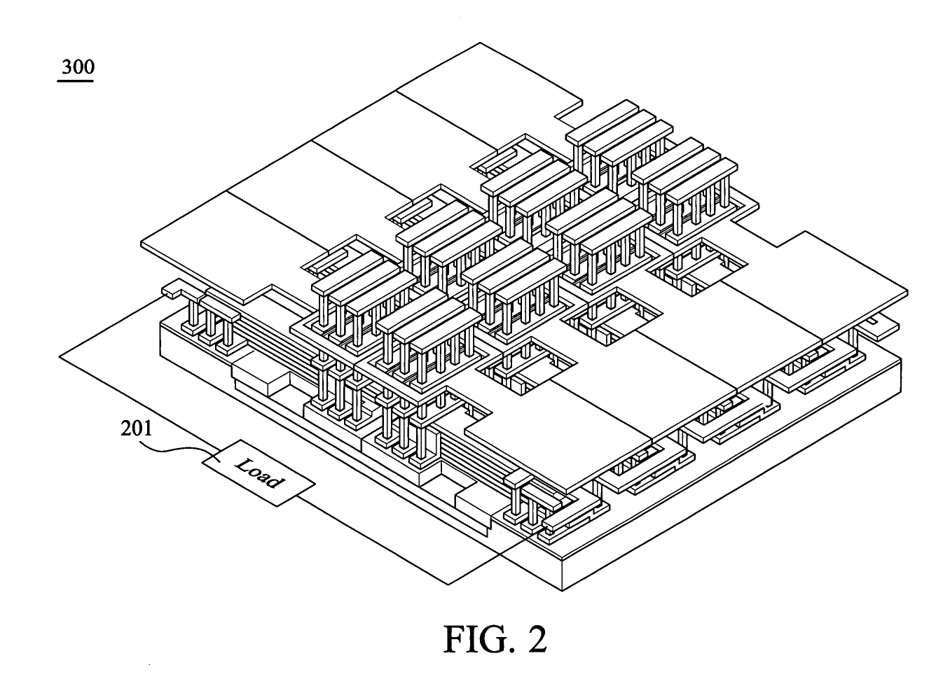

FIG. 2 illustrates an embodiment of an electronic device 300 with the thermoelectric device shown in FIG. 1J. The electronic device 300 can comprise a plurality of thermoelectric devices. These thermoelectric devices are arranged in an array and connected in series via the connection of input/output terminals. The device 300 can be employed for powering a load 201, such as an electronic circuit or component or other external electronic devices. The number of the thermoelectric devices is based on the requirement of power for the load 201.

In some embodiments, one or more thermoelectric devices can be integrated with CMOS circuits on a chip for powering the CMOS circuits without providing additional power source.

According to the invention, the thermoelectric device can provide more power for integrated circuits or electronic components and improve thermal converting performance by stacking more thermoelectric couples in the same area of a chip without increasing the used area of the chip. Moreover, the stacked thermoelectric devices can be integrated with the CMOS circuit on the same chip, thereby simplifying the fabrication process for system-on-chip applications. Additionally, since the thermal insulating cavity is formed after formation of the interconnect structures, device damage can be mitigated and device fabrication can be more stable, increasing device reliability.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A thermoelectric device, comprising:
a substrate comprising a thermal insulating region and a thermal conductive region, wherein a first dielectric layer is formed on the substrate of the thermal insulating region and a thermal insulating cavity formed between the substrate and the overlying first dielectric layer;
a stack structure overlying the substrate of the thermal insulating and conductive regions, comprising a plurality of thermoelectric material layers insulated from each other; and
first and second interconnect structures overlying the substrate of the thermal insulating region and the thermal conductive region, respectively, electrically connecting the stack structure.

2. The device of claim 1, wherein the thermal conductive region, the stack structure and the first interconnect structure create a heat flux path, such that a voltage is output from the second interconnect structure when heat through the heat flux path from the bottom surface of the substrate.

3. The device of claim 1, further comprising a second dielectric layer formed between the stack structure and the substrate of the thermal conductive region.

4. The device of claim 3, wherein the first dielectric layer is thicker than the second dielectric layer.

5. The device of claim 1, wherein the first dielectric layer comprise a field oxide.

6. The device of claim 1, wherein the thermoelectric material layers, comprise a plurality of first semiconductor layers with a first type conductivity and a plurality of second semiconductor layers with a second type conductivity opposite to the first type conductivity, wherein the first and second semiconductor layers are alternately arranged.

7. The device of claim 1, wherein the thermoelectric layers comprise silicon.

8. The device of claim 1, wherein the thermoelectric material layers comprise three n-type polysilicon layers and three p-type polysilicon layers, wherein the n-type and p-type polysilicon layers are alternately arranged.

9. A chip comprising a CMOS circuit and at least one thermoelectric device of claim 1 powering the CMOS circuit.

10. An electronic device comprising more than one thermoelectric device of claim 1 arranged in an array and electrically connected to each other.

11. A method for fabricating a thermoelectric device, comprising:
providing a substrate comprising a first region and a second region;
forming first and second dielectric layers overlying the substrate of the first and second regions, respectively, wherein the first dielectric layer is thicker than the second dielectric layer;
forming a stack structure overlying first and second dielectric layers, comprising a plurality of thermoelectric material layers insulated from each other; and
forming first and second interconnect structures overlying the substrate of the first and second regions, respectively, electrically connecting to the stack structure.

12. The method of claim 11, further comprising:
etching the first dielectric layer to expose a portion of the underlying substrate; and
isotropically etching the exposed substrate to form a cavity therein and underlying the first dielectric layer.

13. The method of claim 12, wherein the first dielectric layer is etched by reactive ion etching using C₄F₈ as an etchant.

14. The method of claim 12, wherein the substrate is isotropically etched using SF₆ as an etchant.

15. The method of claim 11, wherein the thermoelectric material layers comprise a plurality of first semiconductor layers with a first type conductivity and a plurality of second semiconductor layers with a second type conductivity opposite to the first type conductivity, wherein the first and second semiconductor layers are alternately arranged.

16. The method of claim 15, wherein the first and second semiconductor layers comprise silicon.

17. The method of claim 11, wherein the thermoelectric material layers comprises three n-type polysilicon layers and three-p-type polysilicon layers, wherein the n-type and p-type polysilicon layers are alternately arranged.

18. The method of claim 11, wherein the first dielectric layer is formed by LOCOS or STI method.

19. The method of claim 11, wherein the second dielectric layer is formed by thermal oxidation.
